(19) United States
(12) Patent Application Publication
(10) Pub. No.: US 2026/0238217 A1
(43) Pub. Date: Aug. 13, 2026

(54) HYBRID ADC

(71) Applicant: Hiroaki TAKEHANA, Tokyo (JP)

(72) Inventor: Hiroaki TAKEHANA, Tokyo (JP)

(73) Assignee: MITSUMI ELECTRIC CO., LTD., Tokyo (JP)

(21) Appl. No.: 19/156,610

(22) PCT Filed: Feb. 21, 2024
(86) PCT No.: PCT/JP2024/006301

§ 371 Date: Aug. 14, 2025

(30) Foreign Application Priority Data
Mar. 10, 2023 (JP) 2023-037799

(51) Int. Cl. H03M 1/08

(52) U.S. Cl. CPC H03M 1/0854

(57) ABSTRACT

To provide a hybrid ADC that is capable of suppressing the influence of quantization error and with improved linear characteristics.

The hybrid ADC includes a first switch coupled to an input terminal to which an analog signal is to be input; a delay integrator coupled to an output side of the first switch; a quantizer coupled to an output side of the delay integrator; a digital-to-analog converter configured to perform analog conversion of an output of the quantizer; and a first adder provided between the first switch and the delay integrator, and configured to add the analog signal that is input to the first switch and an inverted output obtained by inverting a sign of an output of the digital-to-analog converter. In a first step, the first switch is configured to be turned on, the quantizer is configured to perform 2-level quantization, and the digital-to-analog converter is configured to perform 2-level analog conversion. In a second step, the first switch is configured to be turned off, the quantizer is configured to perform 3-level quantization, and the digital-to-analog converter is configured to perform 3-level analog conversion, based on the output of the delay integrator in the first step.

### TECHNICAL FIELD

The present invention relates to a hybrid ADC.

### BACKGROUND

Conventionally, there has been a cyclic A/D (analog to digital) converter that converts an analog signal to a digital signal by repeatedly performing comparison operations sequentially from the most significant bit to the least significant bit. The cyclic A/D converter includes an arithmetic clock generating unit that generates an arithmetic clock based on an input master clock such that a computation cycle corresponding to each bit decreases sequentially from the most significant bit to the least significant bit. The cyclic A/D converter also includes an A/D converting unit that repeatedly performs the comparison operations sequentially from the most significant bit to the least significant bit by using the arithmetic clock generated by the arithmetic clock generating unit (see, for example, Patent Document 1).

### RELATED-ART DOCUMENTS

### Patent Document

Patent Document 1: Japanese Unexamined Patent Application Publication No. 2011-171974

### SUMMARY

### Problem to be Solved by the Invention

Here, in a hybrid ADC configuration including an incremental ADC (IADC) that resets a delta-sigma ADC (Analog to Digital Converter) at each OSR (Over Sampling Rate); and a cyclic ADC that takes a residual from the IADC as input, when a quantizer and a DAC are set to three levels, correction can be performed when quantization error occurs due to thermal noise or the like.

However, when the quantizer and the DAC are set to the three levels, nonlinearity of the DAC becomes an issue.

Accordingly, an object is to provide a hybrid ADC that is capable of suppressing the influence of quantization error and has improved linear characteristics.

### Means for Solving the Problem

A hybrid ADC of an embodiment of the present invention includes a first switch coupled to an input terminal to which an analog signal is to be input; a delay integrator coupled to an output side of the first switch; a quantizer coupled to an output side of the delay integrator; a digital-to-analog converter configured to perform analog conversion of an output of the quantizer; and a first adder provided between the first switch and the delay integrator, and configured to add the analog signal that is input to the first switch and an inverted output obtained by inverting a sign of an output of the digital-to-analog converter. In a first step, the first switch is configured to be turned on, the quantizer is configured to perform 2-level quantization, and the digital-to-analog converter is configured to perform 2-level analog conversion. In a second step, the first switch is configured to be turned off, the quantizer is configured to perform 3-level quantization, and the digital-to-analog converter is configured to perform 3-level analog conversion, based on the output of the delay integrator in the first step.

### Effects of the Invention

A hybrid ADC that is capable of suppressing the influence of quantization error and has improved linear characteristics can be provided.

### BRIEF DESCRIPTION OF THE DRAWINGS

FIG. 1 shows a configuration example of a hybrid ADC 100 according to a first embodiment.

FIG. 2A shows an example of a circuit configuration in a first step.

FIG. 2B shows an example of a circuit configuration in a second step.

FIG. 3A shows output D1 of an integrator 180A in the first step and output D of an arithmetic unit 180C in the second step.

FIG. 3B shows 16-bit total output of the hybrid ADC 100 in binary as an example.

FIG. 4 shows a cyclic ADC 200 according to a second embodiment.

FIG. 5 shows an example of digital code and operation weight in cycles 1 to N of the cyclic ADC 200.

FIG. 6A shows an operational example of a typical cyclic ADC that performs correct conversion.

FIG. 6B shows an operational example of the typical cyclic ADC that makes an error in quantization.

FIG. 7 is a diagram for describing an operational example of the cyclic ADC 200 that corrects the error in quantization.

### MODE FOR CARRYING OUT THE INVENTION

Embodiments to which a hybrid ADC of the present invention is applied will be described below.

### First Embodiment

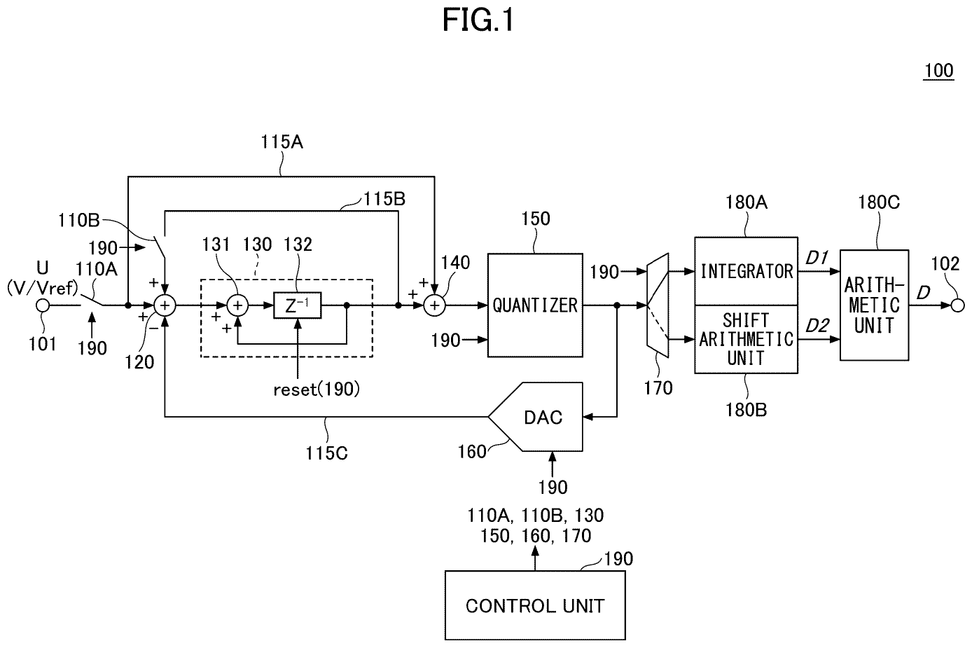

FIG. 1 is a diagram showing a configuration example of a hybrid ADC 100 according to a first embodiment. As an example, the hybrid ADC 100 can be used as an ADC that performs digital conversion of the output of a battery level indicator, a sensor, or the like.

The hybrid ADC 100 includes an input terminal 101, an output terminal 102, a switch 110A, a switch 110B, a line 115A, a line 115B, an adder 120, a delay integrator 130, an adder 140, a quantizer 150, a DAC (Digital to Analog Converter) 160, a DEMUX (Demultiplexer) 170, an integrator 180A, a shift arithmetic unit 180B, an arithmetic unit 180C, and a control unit 190.

The switch 110A is an example of a first switch. The switch 110B is an example of a second switch. The line 115A is an example of a branch line. The line 115B is an example of a feedback loop. The adder 120 is an example of a first adder. The adder 140 is an example of a second adder. The DAC 160 is an example of a digital-to-analog converter. The integrator 180A, the shift arithmetic unit 130B, and the arithmetic unit 180C are examples of output arithmetic units.

The input terminal 101 is an input terminal to which an analog signal U (V/Vref) is input. The switch 110A is connected to an output side of the input terminal 101. As an example, when the hybrid ADC 100 is used in a battery level indicator, a sensor, or the like, a sensor signal or the like indicating a battery level or a detected amount from the sensor is input to the input terminal 101.

The output terminal 102 is connected to an output side of the arithmetic unit 180C. The output terminal 102 outputs a digital signal (total output D) obtained by performing digital conversion of the analog signal U (V/Vref) that is input to the input terminal 101.

The switch 110A is provided between the input terminal 101 and the adder 120. The switch 110A is controlled to open and close by the control unit 190. A state where the switch 110A is open is an off state, and a state where the switch 110A is closed is an on state. The switch 110A is turned on in a first step, and turned off in a second step.

The switch 110B is inserted in series into the line 115B. The switch 110B is controlled to open and close by the control unit 190. A state where the switch 110B is open is an off state, and a state where the switch 110B is closed is an on state. The switch 110B is turned off in the first step, and turned on in the second step.

The line 115A is a line that connects an output side of the switch 110A to one of two input terminals of the adder 140. The analog signal U (V/Vref) that is input to the switch 110A is input to the adder 140 via the line 115A.

The line 115B is a feedback loop that connects an output side of the delay integrator 130 to a positive terminal of one of three input terminals of the adder 120. The switch 110B is inserted in series into the line 115B.

A line 115C is a feedback loop that connects the output side of the delay integrator 130 and a negative terminal among three input terminals of the adder 120. The DAC 160 is inserted in series into the line 115C.

The adder 120 has the above three input terminals and one output terminal. Two of the three input terminals are positive terminals, and the remaining one is the negative terminal. The positive terminals input without inverting a sign of the input, and each negative terminal inverts the sign of the input and then inputs the result.

In the adder 120, the switch 110A and the line 115B are respectively connected to the two positive terminals among the three input terminals. An output terminal of the DAC 160 is connected to the negative terminal of the adder via the line 115C. In the first step, when the switch 110A is on and the switch 110B is off, the adder 120 adds the analog signal U input to the switch 110A; and an inverted output in which a sign of the output of the DAC 160 is inverted. That is, in the first step, the adder 120 subtracts the output of the DAC 160 from the analog signal U input to the switch 110A. In the second step, when the switch 110A is off and the switch 110B is on, the adder 120 adds the output of the delay integrator 130; and the inverted output in which the sign of the output of the DAC 160 is inverted. That is, in the second step, the adder 120 subtracts the output of the DAC 160 from the output of the delay integrator 130.

The delay integrator 130 is provided between the adder 120 and the adder 140. The delay integrator 130 has an adder 131 and a holding unit 132. The holding unit 132 holds the output of the adder 131 from one cycle earlier. An output terminal of the holding unit 132 is connected to one input terminal of the adder 131 by a feedback loop in the delay integrator 130, and is connected to the other input terminal of the adder 140. The other input terminal of the adder 131 is connected to the output terminal of the adder 120, and the output terminal of the adder 131 is connected to an input terminal of the holding unit 132. The adder 131 adds the output of the holding unit 132 and the output of the adder 131, and outputs the result to the holding unit 132. The holding unit 132 resets a value that is held at the end of each cycle in the first step and second step, and holds the output of the adder 131 at the end of each cycle. As a result, in a subsequent cycle, the holding unit 132 holds the output of the adder 131 from one cycle earlier.

In the adder 140, one input terminal is connected to the output side of the switch 110A, the other input terminal is connected to the output terminal of the holding unit 132 of the delay integrator 130, and the output terminal is connected to an input terminal of the quantizer 150.

In the quantizer 150, the input terminal is connected to the output terminal of the adder 140, and an output terminal is connected to both an input terminal of the DAC 160 and an input terminal of the DEMUX 170. The quantizer 150 quantizes the analog signal that is input from the adder 140, and outputs a digital code. The quantizer 150 can perform 2-level or 3-level quantization. The switching is performed by the controller 190. The quantizer 150 performs the 2-level quantization in the first step, and performs the 3-level quantization in the second step. Two levels are 1 and −1. Three levels are 1, 0, and −1.

The DAC 160 is inserted in series into the line 115C that is a feedback loop connecting an output side of the quantizer 150 and the negative terminal of the adder 120. The DAC 160 performs analog conversion of the output (digital code) of the quantizer 150, and outputs the result. The DAC 160 can perform 2-level or 3-level analog conversion. The switching is performed by the control unit 190. The DAC 160 performs the 2-level analog conversion in the first step, and performs the 3-level analog conversion in the second step. The two levels are +Vref(V) and −Vref(V). The three levels are +Vref (V), 0 (V), and −Vref (V).

The DEMUX 170 has an input terminal connected to the output terminal of the quantizer 150, and two output terminals connected respectively to the integrator 180A and the shift arithmetic unit 180B. The DEMUX 170 connects the input terminal to one of the above two output terminals. The switching is performed by the control unit 190. The DEMUX 170 connects the in-out terminal to the integrator 180A in the first step, and connects the input terminal to the shift arithmetic unit 180B in the second step.

The integrator 180A integrates the output (digital code) of the quantizer 150 that is provided via the DEMUX 170, and outputs the result to the arithmetic unit 180C.

The shift arithmetic unit 180B outputs the output (second output) that is obtained by shifting the output (digital code) of the quantizer 150 provided via the DEMUX 170, to the arithmetic unit 180C in the second step.

The computing unit 180C adds the output of the shift arithmetic unit 180B in the second step (second output) to the output of the integrator 180A in the first step (first output), and outputs a total output D obtained by truncating a value of the least significant bit of the sum of the first output and second output.

The control unit 190 is composed of a digital circuit (ASIC), turns the switches 110 and 110B on and off, and resets the holding unit 132 of the delay integrator 130. The control unit 190 also switches the number of levels in the quantizer 150 and the DAC 160, performs switching of the DEMUX 170, and the like. The control unit 190 may be composed of a microcontroller (MCU).

### <Circuit Configuration in First Step and Second Step>

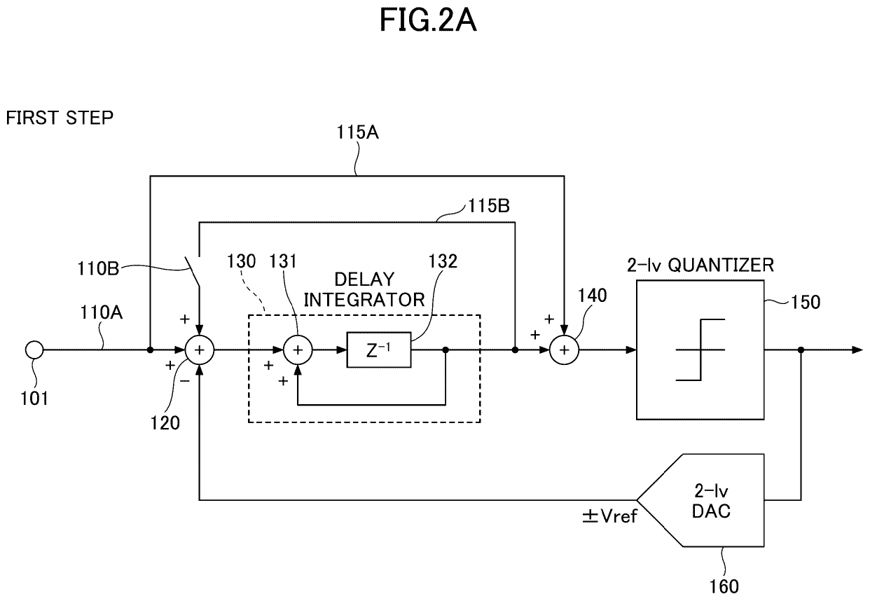

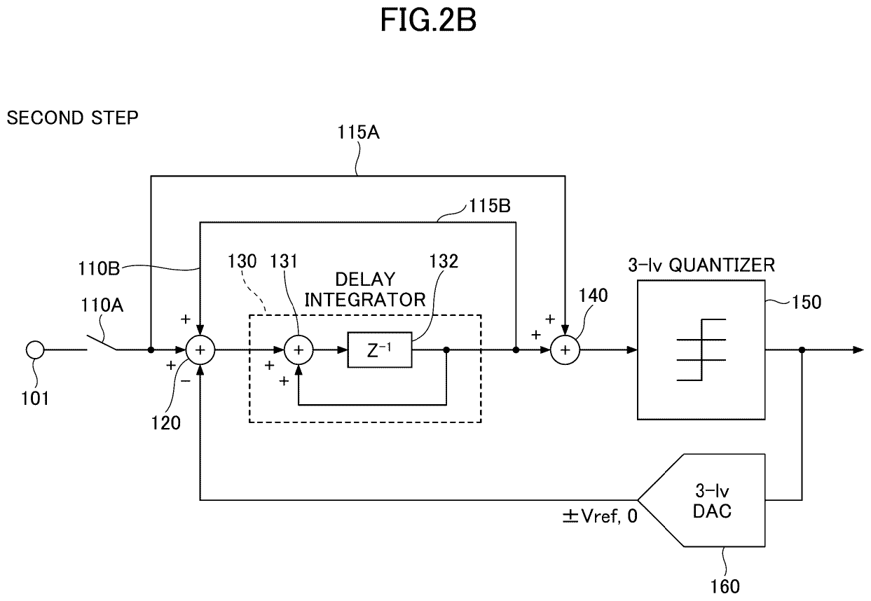

FIG. 2A shows an example of the circuit configuration in the first step. FIG. 2B shows an example of the circuit configuration in the second step. In FIGS. 2A and 2B, the DEMUX 170, the integrator 180A, the shift arithmetic unit 180B, an arithmetic unit 180C, and a control unit 190 are omitted.

As shown in FIG. 2A, in the first step, the switch 110A is turned on, the switch 110B is turned off, and the quantizer 150 and the DAC 160 are each set to two levels. In this case, in the first step, the hybrid ADC 100 adds the analog signal U (V/Vref) input to the input terminal 101 and the output of the delay integrator 130 (output of holding unit 132), by using the adder 140, performs 2-level quantitation by using the quantizer 150, and provides feedback to the adder 120 by using the DAC 160. By repeating such cycles, the hybrid ADC 100 operates as a delta sigma ADC in the first step. The output of the quantizer 150 in each cycle of the first step is integrated by the integrator 180A.

When K represents the number of cycles that perform repetitive operations in the first step. Each cycle is performed at each OSR (Over Sampling Rate) of the hybrid ADC 100. In this case, K digital codes from Q1[1], . . . , to Q1[K] are obtained as the output from the quantizer 150. In this arrangement, an output D1 of the integrator 180A is expressed by the following equation (1). K=2^{M} is given, and M-bit output D1 is obtained in the first step.

$$\begin{matrix}[ Math . 1 ] & \\ D 1 = {\sum }_{i = 1}^{K} Q 1 [ i ] & ( 1 )\end{matrix}$$

As shown in FIG. 2B, in the second step, the switch 110 is turned off, the switch 110B is turned on, and the quantizer 150 and the DAC 160 are each set to three levels. In this case, in the second step, in the hybrid ADC 100, the quantizer 150 performs 3-level quantization of a value X that is held in the holding unit 132 of the delay integrator 130 in the K-th cycle of the first step, and then the DAC 160 performs 3-level analog conversion of the digital code output from the quantizer 150. By repeating such cycles N times, the hybrid ADC 100 operates as a cyclic ADC.

In the second step, when the cyclic operation is performed for N cycles, N digital codes from Q2[1], . . . , to Q2[N] are obtained as the output from the quantizer 150. In this arrangement, an output D2 of the shift arithmetic unit 180B is expressed by the following equation (2). By performing the cyclic operation for N cycles, the output D2 of N+1 bits is obtained.

$$\begin{matrix}[ Math . 2 ] & \\ \begin{matrix}D 2 = {\sum }_{i = 1}^{N} ( Q 2 [ i ] \times {2}^{N - 1} ) \\ = Q 2 [ 1 ] \times {2}^{N - 1} + Q 2 [ 2 ] \times {2}^{N - 2} + … + Q 2 [ N ]\end{matrix} & ( 2 )\end{matrix}$$

As a result, the total output D output from the arithmetic unit 180C is expressed by the following equation (3).

$$\begin{matrix}[ Math . 3 ] & \\ D = D 1 \times {2}^{N} + D 2 & ( 3 )\end{matrix}$$

### <Operation of Hybrid ADC 100>

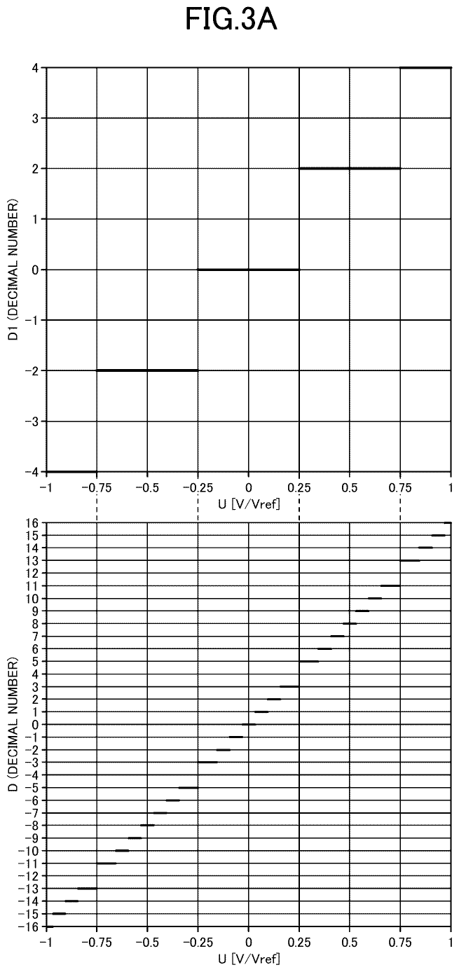

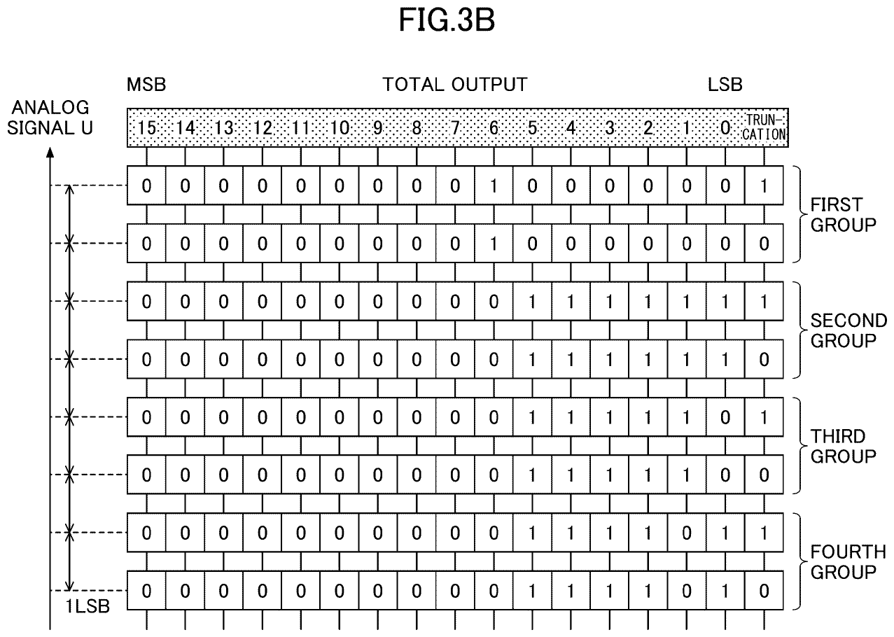

FIG. 3A shows both the output D1 of the integrator 180A in the first step and the output D of the arithmetic unit 180C in the second step. The upper side of FIG. 3A shows the output D1 of the integrator 180A in the first step in decimal, and the lower side of FIG. 3A shows the total output D of the arithmetic unit 180C in the second step in decimal. The horizontal axes in the upper side and lower side of FIG. 3A represent the analog signals U (V/Vref) input to the input terminal 101.

As shown in the upper side of FIG. 3A, in the first step, for example, when the number of cycles is 4, a value of the output D1 takes discrete values that include −4 when the analog signal U (V/Vref) is −1 to 0.75; −2 when the analog signal U (V/Vref) is −0.75 to −0.25; 0 when the analog signal U (V/Vref) is −0.25 to 0.25; 2 when the analog signal U (V/Vref) is 0.25 to 0.75; and 4 when the analog signal U (V/Vref) is 0.75 to 1. In the first step, the quantizer 150 and DAC 160 operate at two levels.

In the second step, as shown in the lower side of FIG. 3A, when the number of cycles is 2, the total output D takes values from −16 to 16 in a case where the analog signal U (V/Vref) varies from −1 to 1, and the resulting resolution increases. However, −12, −4, 4, and 12 are missing. In other words, miscoding occurs in the total output D when the analog signal U (V/Vref) is at −0.75, −0.25, 0.25, and 0.75. The miscoding occurs at analog signals U (V/Vref) of −0.75, −0.25, 0.25, and 0.75, where a value of the output D1 switches. The miscoding occurs due to quantization error caused by thermal noise.

The hybrid ADC 100 suppresses the influence of such a miscode as follows. FIG. 3B shows, as an example, 16-bit total output of the hybrid ADC 100 in binary. In the example, the output D1 of 10 bits (M=10) is obtained in the first step, and 7-bit output (N+1=7, where N=6) is obtained in the second step.

10 values from 15 to 6, including the 15th most significant bit as shown in FIG. 3B are used as 10-bit output D1 obtained in the first step, and 7 values, including bits 5 to 0 and a truncated bit, are used as 7-bit output D2 that is obtained in the second step.

FIG. 3B shows two total outputs (third group) when two analog signals U, in each of which a 7-bit value from 6 to 0 of the hybrid ADC 100 is 0111110, are input. A difference between the two analog signals U corresponds to a difference between 1LSBs. FIG. 3B shows two total outputs (fourth group) when the two analog signals U, in each of which the 7-bit value from 6 to 0 of the hybrid ADC 100 is 0111101, are input. The difference between the two analog signals U corresponds to a difference between 1LSBs.

In each of a first group to the fourth group, the least significant bits (truncated bits) of two total outputs D differ from each other in 1 and 0, but 16-bit values from 15 to 0 are identical. In this arrangement, even if miscoding occurs, the hybrid ADC 100 outputs, as the total output, an output obtained by the shift arithmetic unit 180B that calculates an output with one more bit than the number of bits of the second output in the second step, and by the arithmetic unit 180C that truncates a value of the least significant bit of the sum of the first output in the first step and the second output in the second step. In this arrangement, the influence of the miscode can be suppressed.

As described above, by excluding the least significant bit (truncated bit) of the sum of the first output in the first step and the second output in the second step, the influence of the miscode can be suppressed even if miscoding occurs.

### <Effects>

The hybrid ADC 100 includes a switch 110A (first switch) connected to an input terminal to which an analog signal is input; a delay integrator 130 connected to an output side of the switch 110A (first switch); a quantizer 150 connected to an output side of the delay integrator 130, a DAC 160 that performs analog conversion of the output of the quantizer 150; and an adder 120 (first adder) that is provided between the switch 110A (first switch) and the delay integrator 130 and that adds the analog signal input to the switch 110A (first switch) and an inverted output obtained by inverting a sign of the output of the DAC 160. In a first step, the switch 110A (first switch) is turned on, the quantizer 150 performs 2-level quantization, and the DAC 160 performs 2-level analog conversion. In a second step, the switch 110A (first switch) is turned off, the quantizer 150 performs 3-level quantization based on the output of the delay integrator 160 in the first step, and the DAC 130 performs 3-level analog conversion. By performing the 2-level quantization in the first step, linearity can be ensured, and by performing 3-level quantization in the second step, the influence of quantization error due to thermal noise can be suppressed.

As a result, it is possible to provide the hybrid ADC 100 that can suppress the influence of quantization error and has improved linear characteristics.

Further, a hybrid ADC may further include an output arithmetic unit connected to an output side of a quantizer 150. The output arithmetic unit adds second output of the quantizer 150 in a second step to first output of the quantizer 150 in a first step, and outputs a total output in which a value of the least significant bit of the sum of the first output and the second output is truncated. Since an arithmetic unit 180C outputs the total output in which the value of the least significant bit of the sum of the first output and the second output is truncated, it is possible to provide a hybrid ADC 100 that can suppress the influence of quantization error more reliably and has improved linear characteristics.

A hybrid ADC may further include a line 115B (line 115B (feedback loop)) that feeds the output of a delay integrator 130 back to an adder 120 (first adder); and a switch 110B (second switch) that is inserted in series into a line 115B (feedback loop). In a first step, the switch 110B (second switch) is turned off, and in a second step, the switch 110B (second switch) is turned on, and in the second step, the adder 120 (first adder) adds an inverted output of a DAC 160 and the output of a delay integrator 130 that is fed back by the line 115B (feedback loop). In the second step, a value obtained by subtracting the output of the DAC 160 from the output of the delay integrator 130 can be input to the delay integrator 130. Circuit blocks such as the delay integrator 130 and the adder 140 can be shared between an IADC in the first step and a cyclic ADC in the second step, and a circuit area can be reduced.

A hybrid ADC may further include a line 115A (branch line) branching between a switch 110A (first switch) and an adder 120 (first adder); and an adder 140 (second adder) provided between a branch point where a line 115B (feedback loop) branches at an output side of a delay integrator 130 and an input terminal of a quantizer 150. The adder 140 adds the output of a delay integrator 130 and an analog signal input via the line 115A (branch line). In a first step, the hybrid ADC has the effect of adding a quantization error from one cycle earlier, to an analog input U (a function of a delta sigma ADC). In a second step, since the switch 110A (first switch) is turned off, a line 115A is treated as 0 V and its voltage is not added, and the resulting output of a delay integrator 130 is directly input to the quantizer 150. Therefore, a delta sigma ADC can be constructed in the first step by including the line 115A (branch line) and the adder 140 (second adder).

### Second Embodiment

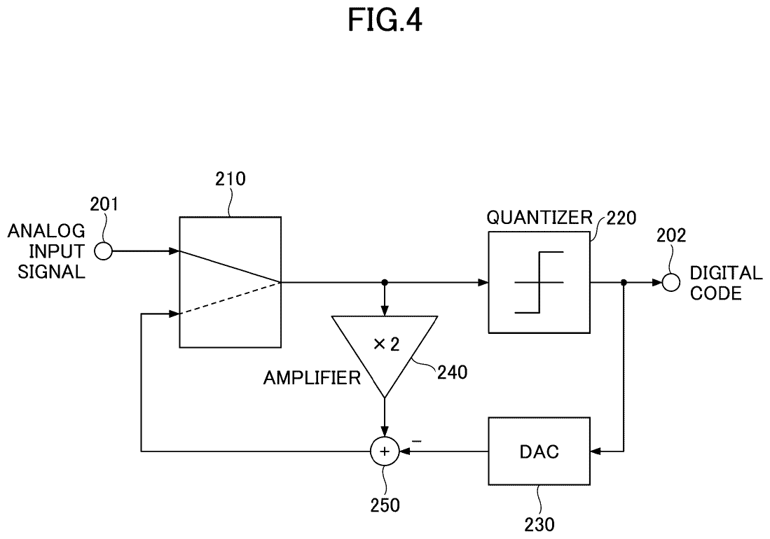

FIG. 4 is a diagram showing a cyclic ADC 200 according to a second embodiment. The cyclic ADC 200 includes an input terminal 201, an output terminal 202, a MUX (multiplexer) 210, a quantizer 220, a DAC 230, an amplifier 240, and an adder 250.

The input terminal 201 is connected to one input terminal of the MUX 210. The input terminal 201 is an input terminal to which an analog signal is input. As an example, when the cyclic ADC 200 is used in a battery level indicator, a sensor, or the like, a sensor signal or the like indicating a detected amount from the sensor, a battery level, or the like is input to the input terminal 201.

The output terminal 202 is connected to an output unit of the quantizer 220. A shift arithmetic unit similar to the shift arithmetic unit 180B of the hybrid ADC 100 according to the first embodiment is connected to the output terminal 202. The output terminal 202 outputs a digital signal obtained by performing digital conversion of the analog signal that is input to the input terminal 201.

The MUX 210 connects an output terminal to either the input terminal 201, which is connected to one input terminal, or an output terminal of the adder 250 that is connected to the other input terminal. The MUX 210 connects the output terminal to the input terminal 201 in a first cycle, and connects the output terminal to the output terminal of the adder 250 in a second cycle and subsequent cycles. The output terminal of the MUX 210 is connected to an input terminal of the quantizer 220 and an input terminal of the amplifier 240.

The quantizer 220 quantizes the output of the MUX 210, and outputs the result as a digital code. The quantizer 220 performs 2-level quantization. An output of the quantizer 220 is 1 or 0. An output terminal of the quantizer 220 is connected to the output terminal 202 and an input terminal of the DAC 230.

The DAC 230 is inserted in series into a feedback loop that provides feedback to the adder 250 from an output side of the quantizer 220. The DAC 230 performs analog conversion of the output (digital code) of the quantizer 220, and outputs the result to a negative terminal of the adder 250. The DAC 230 performs 2-level analog conversion (+Vref, 0).

The amplifier 240 is connected between the output terminal of the MUX 210 and a positive terminal of the adder 250. As an example, gain of the amplifier 240 is doubled (×2). The amplifier 240 doubles the output of the MUX 210 and outputs the result to the positive terminal of the adder 250.

The adder 250 has the positive terminal that is connected to the output terminal of the amplifier 240; the negative terminal that is connected to the output terminal of the DAC 230; and an output terminal connected to the other input terminal of the MUX 210.

The adder 250 outputs a signal obtained by subtracting the output of the DAC 230 from the output of the amplifier 240, to the other input terminal of the MUX 210.

The cyclic ADC 200 performs cyclic operation in which the quantizer 220 quantizes the analog signal input to the input terminal 201 in the first cycle, and in which the quantizer 220 quantizes the output of the adder 250 in the second cycle and subsequent cycles.

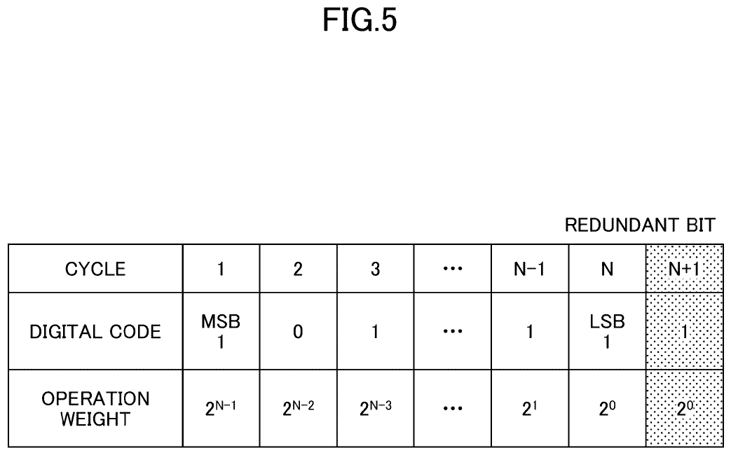

FIG. 5 shows an example of the digital code and operation weight in cycles 1 to N of the cyclic ADC 200. The operation weight is a weight caused by the amplifier 240 that doubles the output of the adder 250 each time the cycle is repeated, and the operation weight represents a weight for the least significant bit.

As shown in FIG. 5, the cyclic ADC 200 performs cyclic operation for N+1 cycles to obtain an N-bit digital code. In this case, the digital code exists from 1 (MSB) in the first cycle to 1 in the (N+1)th cycle, which follows 1 (LSB) in the Nth cycle. In addition, the operation weight is 2^{N-1} in the first cycle, and for each subsequent cycle, the power number decreases by one and becomes 2° in the Nth cycle. In the (N+1)th cycle following 1 (LSB) in the Nth cycle, the operation weight is conveniently set to 2°, which is the same value as in the Nth cycle.

### <Typical Cyclic ADC Operation>

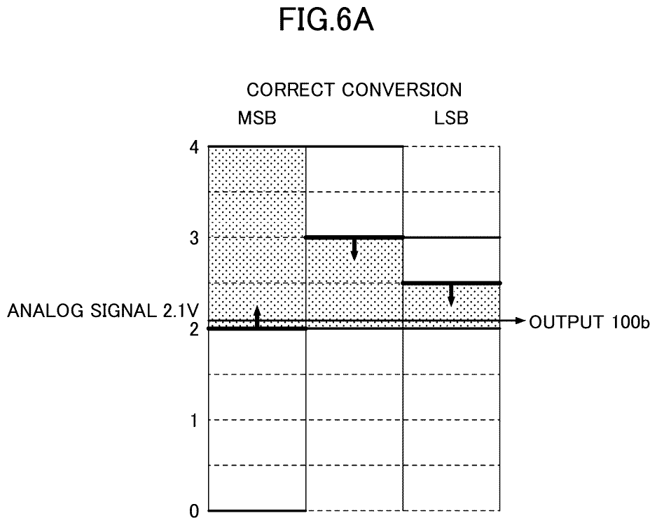

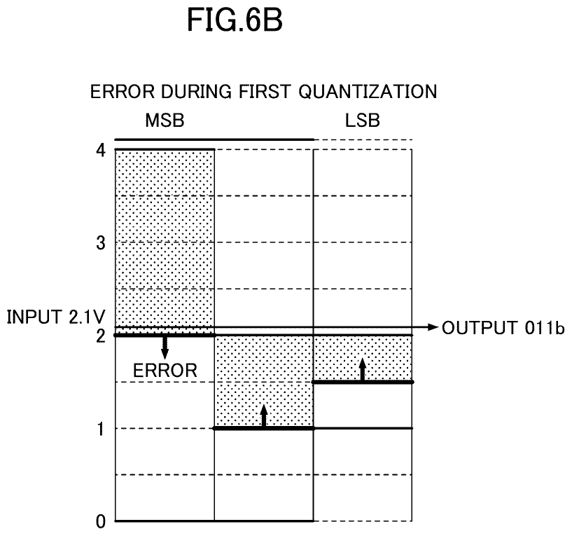

FIG. 6A shows an operational example of a typical cyclic ADC performing correct conversion. In this description, a case of obtaining 3-bit output in the range of 0 V to 4 V is provided as follows. FIG. 6A shows the conversion of three bits from left to right. The leftmost part is the conversion (quantization) for obtaining the MSB, and the rightmost part is the conversion (quantization) for obtaining the LSB.

In quantization for determining the MSB, when the analog signal is 2.1 V, the cyclic ADC performs quantization using 2 V as a reference value, which is a median value in the range of 0 V to 4 V, and then the cyclic ADC outputs digital code 1 because the analog signal of 2.1 V is greater than the reference value of 2 V.

Next, the cyclic ADC that has output the digital code 1 performs quantization using 3 V as the reference value, which is a median value of the upper half from 2 V to 4 V within the range of 0 V to 4 V, and then the cyclic ADC outputs digital code 0 because the analog signal of 2.1 V is less than the reference value of 3 V.

Next, in quantization for determining the LSB, the cyclic ADC that has output the digital code 0 performs quantization using 2.5 V as the reference value, which is a median value of the lower half from 2 V to 3 V within the range of 2 V to 4 V, and then the cyclic ADC outputs digital code 0 because the analog signal of 2.1 V is less than the reference value of 2.5 V.

As described above, when the analog signal of 2.1 V is input, the cyclic ADC outputs 3-bit output 100b. Note that the above represents the overall concept of the conversion, but actually, by the adder 250 that performs an operation on both the output of the amplifier 240 that receives the analog signal, and the output of the DAC 230, the quantizer 220 performs conversion and arithmetic operations using an analog input value within the range of 0 V to 4 V and a reference voltage of 2 V.

FIG. 6B shows an operational example of the typical cyclic ADC that makes an error in quantization. In this description, a case of obtaining 3 bits in the range of 0 V to 4 V is provided. Similar to FIG. 6A, FIG. 6B shows the conversion of three bits from left to right.

The leftmost part is the conversion for obtaining the MSB (quantization), and the rightmost part is the conversion (quantization) for obtaining the LSB.

In quantization for determining the MSB, when the analog signal is 2.1 V, the cyclic ADC uses 2 V as the reference value, which is a median value in the range of 0 V to 4 V, to perform quantization. However, the cyclic ADC outputs digital code 0 by making an error in quantization.

Next, the cyclic ADC that has output the digital code 0 uses 1 V as the reference value, which is a median value of the lower half from 0 V to 2 V within the range of 0 V to 4 V, to perform quantization. The cyclic ADC outputs digital code 1 because the analog signal of 2.1 V is greater than the reference value of 1 V.

Next, in quantization for determining the LBS, the cyclic ADC that has output the digital code 1 quantizes the LSB using 1.5 V as the reference value, which is a median value of the upper half from 1 V to 2 V within the range of the 0 V to 2 V, and then the cyclic ADC outputs digital code 1 because the analog signal of 2.1 V is greater than the reference value of 1.5 V.

As described above, when the analog signal of 2.1 V is input, the cyclic ADC outputs 3-bit output 011b. This quantization includes an error.

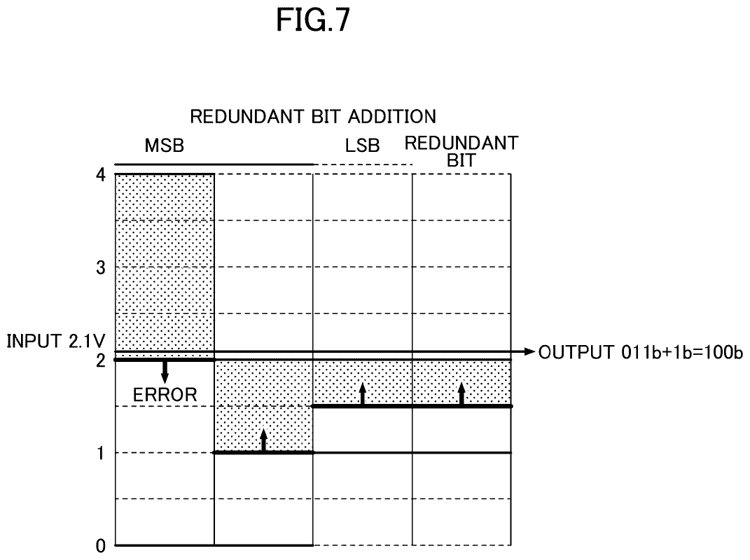

The cyclic ADC 200 according to the second embodiment corrects the error in quantization as follows. FIG. 7 is a diagram for describing an operational example of the cyclic ADC 200 that corrects the error in quantization.

Here, a case in which the cyclic ADC 200 makes the error in first quantization will be described, as in the operation of FIG. 6B.

In FIG. 7, in quantization for determining the MSB, when the analog signal is 2.1 V, the cyclic ADC performs quantization using 2 V as a reference value, which is a median value in the range of 0 V to 4 V. In this case, the cyclic ADC outputs digital code 0 by making an error in quantization.

Next, the cyclic ADC that has output the digital code 0 performs quantization using 1 V as the reference value, which is a median value of the lower half from 0 V to 2 V within the range of 0 V to 4 V, and then the cyclic ADC outputs digital code 1 because the analog signal of 2.1 V is greater than the reference value of 1 V.

Next, the cyclic ADC that has output the digital code 1 performs quantization using 1.5 V as the reference value, which is a median value of the upper half from 1 V to 2 V within the range of 0 V to 2 V, and then the cyclic ADC outputs digital code 1 because the analog signal of 2.1 V is greater than the reference value of 1.5 V. The arrangement up to this point is the same as in FIG. 6B.

Next, the cyclic ADC 200 performs quantization for determining a redundant bit. In the quantization to determine the redundant bit, the same operation as the quantization for determining the LSB is performed again. In other words, the quantization is performed using 1.5 V, which is a median value of 1 V to 2 V, as the reference value. Because the analog signal of 2.1 V is greater than the reference value of 1.5 V, digital code 1 is output.

Then, the cyclic ADC 200 outputs 3-bit output 100b in which a redundant bit 1b is added to the 3-bit output Glib. In this arrangement, a correct result can be obtained similarly to the case described in FIG. 6A.

When the cyclic ADC 200 performs correct quantization as in the operation shown in FIG. 6A, the cyclic ADC 200 quantizes the redundant bit using 2.5 V as the reference value, which is a median value of 2 V to 3 V. The cyclic ADC 200 outputs digital code 0 because the analog signal of 2.1 V is less than the reference value of 2.5 V.

Then, the cyclic ADC 200 outputs 3-bit output 100b in which the redundant bit of 0b is added to the 3-bit output 100b. As a result, the correct result can be obtained even when the redundant bit is determined and added while performing correct quantization.

As described above, when obtaining the output of a desired number of bits, any error in quantization can be corrected by determining and adding a redundant bit under the same conditions as the LSB subsequent to the LSB.

The hybrid ADC of the exemplary embodiments of the present invention has been described above, but the present invention is not limited to the disclosed embodiments, and can be modified and changed in various forms without departing from the scope of the claims.

This international application claims priority to Japanese Patent Application No. 2023-037799, filed on Mar. 10, 2023, the entire contents of which are incorporated herein by reference.

### REFERENCE SIGNS LIST

100 hybrid ADC
101 input terminal
102 output terminal
110A switch (example of a first switch)
110B switch (example of a second switch)
115A line (example of a branch line)
115B line (example of a feedback loop)
120 adder (example of a first adder)
130 delay integrator
131 adder
132 holding unit
140 adder (an example of a second adder)
150 quantizer
160 DAC (an example of a digital-to-analog converter)
170 DEMUX
180A integrator (an example of an output arithmetic unit)
180B shift arithmetic unit (an example of an output arithmetic unit)
180C arithmetic unit (an example of an output operation section)
190 control unit
200 cyclic ADC
201 input terminal
202 output terminal
210 MUX
220 quantizer
230 DAC
240 amplifier
250 adder

1. A hybrid analog-to-digital converter (ADC) comprising:
a first switch coupled to an input terminal to which an analog signal is to be input;
a delay integrator coupled to an output side of the first switch;
a quantizer coupled to an output side of the delay integrator;
a digital-to-analog converter configured to perform analog conversion of an output of the quantizer; and
a first adder provided between the first switch and the delay integrator, and configured to add the analog signal that is input to the first switch and an inverted output obtained by inverting a sign of an output of the digital-to-analog converter,
wherein in a first step, the first switch is configured to be turned on, the quantizer is configured to perform 2-level quantization, and the digital-to-analog converter is configured to perform 2-level analog conversion, and
wherein in a second step, the first switch is configured to be turned off, the quantizer is configured to perform 3-level quantization, and the digital-to-analog converter is configured to perform 3-level analog conversion, based on the output of the delay integrator in the first step.

2. The hybrid ADC according to claim 1, further comprising:
an output arithmetic circuit coupled to the output side of the quantizer, and configured to:
add a second output of the quantizer in the second step to a first output of the quantizer in the first step, and
output a total output obtained by truncating a value of the least significant bit of the sum of the first output and the second output.

3. The hybrid ADC according to claim 1, further comprising:
a feedback loop that feeds the output of the delay integrator back to the first adder; and
a second switch inserted in series into the feedback loop,
wherein in the first step, the second switch is configured to be turned off,
wherein in the second step, the second switch is configured to be turned on, and
wherein in the second step, the first adder is configured to add the inverted output of the digital-to-analog converter and the output of the delay integrator that is fed back by the feedback loop.

4. The hybrid ADC according to claim 3, further comprising:
a branch line branching between the first switch and the first adder; and
a second adder provided between a branch point, at which the feedback loop branches on the output side of the delay integrator, and an input terminal of the quantizer, the second adder being configured to add the output of the delay integrator and the analog signal that is input via the branch line.
